(19) United States
(12) Patent Application Publication
(10) Pub. No.: US 2026/0332120 A1
(43) Pub. Date: Oct. 22, 2026

(54) TRANSMITTING DEVICE

(71) Applicant: ROHM Co., Ltd., Kyoto (JP)

(72) Inventor: Shuji Furuichi, Kyoto (JP)

(73) Assignee: ROHM Co., Ltd., Kyoto (JP)

(21) Appl. No.: 19/646,583

(22) Filed: Apr. 14, 2026

(30) Foreign Application Priority Data
Apr. 21, 2025 (JP) 2025-069464

(51) Int. Cl. H03H 7/38; H04B 1/04

(52) U.S. Cl. CPC H03H 7/38; H04B 1/04

(57) ABSTRACT

A transmitting device transmits a transmission signal to a receiving device via a transmission line having a terminal resistance and the receiving device connected to one end thereof. The transmitting device includes: an impedance matching resistance having one end thereof connected to the other end of the transmission line and the other end thereof connected to the transmitting device; a transmission circuit that generates a transmission signal and outputs the generated transmission signal to the other end of the impedance matching resistance; and a terminal resistance abnormality detection circuit that outputs an abnormality detection signal indicating that the terminal resistance is not normally connected to the transmission line when a voltage difference between a voltage at one end of the impedance matching resistance and a voltage at the other end of the impedance matching resistance becomes less than a predetermined threshold voltage.

### CROSS-REFERENCE TO RELATED APPLICATION

This application claims the priority benefits of Japanese application no. 2025-069464, filed on Apr. 21, 2025. The entirety of the above-mentioned patent application is hereby incorporated by reference herein and made a part of this specification.

### SUMMARY

### Technical Field

The disclosure relates to a transmitting device.

### Description of Related Art

Currently, communication is performed to transmit an analog video signal via a coaxial cable having a terminal resistance connected on the receiving device side.

Further, a proposal has been made to provide a terminal detection circuit on the transmitting device side that transmits a video signal, and the terminal detection circuit detects that the terminal resistance has been disconnected from the coaxial cable in the case where the pedestal level during the vertical blanking period of the video signal becomes greater than a predetermined threshold (see Patent Document 1 (Japanese Patent Application Laid-Open No. 2013-62604)).

However, the terminal detection circuit described in Patent Document 1 detects whether the terminal resistance has been disconnected from the coaxial cable by utilizing the pedestal level during the vertical blanking period of the video signal as described above, so the terminal detection circuit is unable to be applied to a transmitting device that transmits a signal other than a video signal.

The transmitting device according to the disclosure is a transmitting device that transmits a transmission signal to a receiving device via a transmission line having a terminal resistance and the receiving device connected to one end thereof, and the transmitting device includes: an impedance matching resistance having one end thereof connected to the other end of the transmission line and the other end thereof connected to the transmitting device; a transmission circuit that generates the transmission signal based on an information signal and outputs the generated transmission signal to the other end of the impedance matching resistance; and a terminal resistance abnormality detection circuit that outputs an abnormality detection signal indicating that the terminal resistance is not normally connected to the transmission line in the case where a voltage difference between a voltage at one end of the impedance matching resistance and a voltage at the other end of the impedance matching resistance becomes less than a predetermined threshold voltage.

### BRIEF DESCRIPTION OF THE DRAWINGS

FIG. 1 is a block diagram showing a configuration of a communication system 100 including a transmitting device 10 as a first embodiment.

FIG. 2 is a diagram showing an operation of the terminal resistance abnormality detection circuit 22.

FIG. 3 is a circuit diagram showing an internal configuration of an output unit of the transmission circuit 21 and the terminal resistance abnormality detection circuit 22 as a second embodiment.

FIG. 4 is a waveform diagram showing a signal format of an analog video signal.

FIG. 5 is a block diagram showing a configuration of a communication system 100 including a transmitting device 10A as a third embodiment.

### DESCRIPTION OF THE EMBODIMENTS

### Detailed Description

Hereinafter, embodiments of the disclosure will be described in detail with reference to the drawings.

### First Embodiment

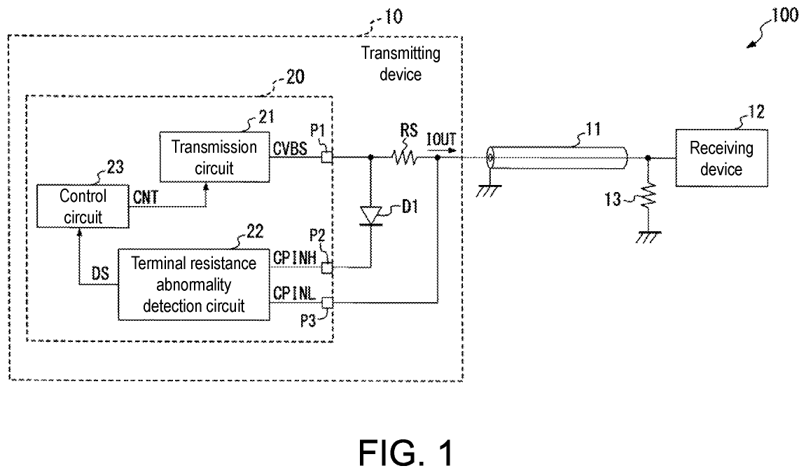

FIG. 1 is a block diagram showing a configuration of a communication system 100 including a transmitting device 10 as a first embodiment.

The communication system 100 includes a transmitting device 10, a coaxial cable 11, a receiving device 12, and a terminal resistance 13.

As shown in FIG. 1, one end of the receiving device 12 and one end of the terminal resistance 13 are connected to one end of an inner conductor of the coaxial cable 11. The terminal resistance 13 has a resistance value identical to the characteristic impedance of the coaxial cable 11, and the other end thereof is grounded together with the outer conductor of the coaxial cable 11.

The transmitting device 10 includes a transmission integrated circuit (IC) chip 20 as a semiconductor IC, a diode D1, and a resistance RS.

As shown in FIG. 1, one end of the resistance RS is connected to the other end of the inner conductor of the coaxial cable 11 and a terminal P3 of the transmission IC chip 20. The other end of the resistance RS is connected to a terminal P1 of the transmission IC chip 20 and an anode of the diode D1. A cathode of the diode D1 is connected to a terminal P2 of the transmission IC chip 20.

The resistance RS is an impedance matching resistance having a resistance value (for example, 75 ohms) identical to the characteristic impedance of the coaxial cable 11.

The transmission IC chip 20 includes a transmission circuit 21, a terminal resistance abnormality detection circuit 22, and a control circuit 23.

The transmission circuit 21 generates a transmission signal CVBS obtained by amplifying an analog information signal, and outputs the transmission signal CVBS via the terminal P1 of the transmission IC chip 20.

The transmission circuit 21 transmits the transmission signal CVBS output from the terminal P1 to the receiving device 12 via the resistance RS and the coaxial cable 11.

The terminal resistance abnormality detection circuit 22 incorporates the voltage at the anode of the diode D1, that is, the voltage generated at the other end of the resistance RS, as a first detection voltage CPINH via the terminal P2. Furthermore, the terminal resistance abnormality detection circuit 22 incorporates the voltage generated at one end of the resistance RS as a second detection voltage CPINL via the terminal 3. That is, the terminal resistance abnormality detection circuit 22 incorporates the voltages generated at both ends of the resistance RS as the first detection voltage CPINH and the second detection voltage CPINL, respectively.

The diode D1 is provided to fix the malfunction that the voltage levels across both ends of the resistance RS temporarily reverse due to noise generated in response to the transmission signal CVBS transitioning steeply from a high level to a low level. That is, in response to the levels of the detection voltages CPINH and CPINL temporarily reversing due to noise, the terminal resistance abnormality detection circuit 22 may perform erroneous detection. Therefore, by providing the diode D1, even in the case of the voltage levels across both ends of the resistance RS reversing, a current is prevented from flowing in the reverse direction at this time, thereby preventing reaction to noise. As the diode D1, for example, a Schottky barrier diode, a fast recovery diode, or a high-speed diode is used.

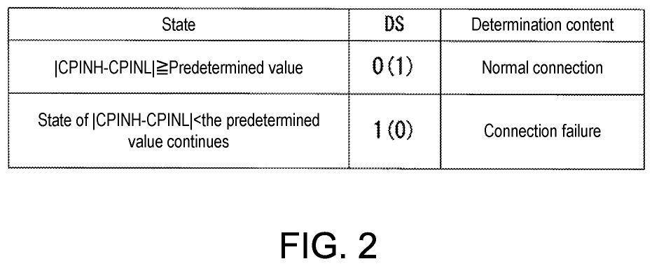

FIG. 2 is a diagram for describing the operation of the terminal resistance abnormality detection circuit 22.

The terminal resistance abnormality detection circuit 22 determines whether the voltage difference between the first detection voltage CPINH and the second detection voltage CPINL (|CPINH−CPINL|), that is, the voltage difference across both ends of the resistance RS, is less than a predetermined threshold voltage.

In the case of determining that the voltage difference is equal to or greater than the predetermined threshold voltage, the terminal resistance abnormality detection circuit 22 determines that the terminal resistance 13 is correctly connected to the coaxial cable 11, and generates a terminal resistance abnormality detection signal DS of logic level 0 (or 1) indicating “normal connection”.

On the other hand, in the case of determining that the voltage difference (|CPINH−CPINL|) is less than the predetermined threshold voltage and the determination result continues for a predetermined period, the terminal resistance abnormality detection circuit 22 determines that the terminal resistance 13 is not normally connected to the coaxial cable 11, and generates a terminal resistance abnormality detection signal DS of logic level 1 (or 0) indicating “connection failure”.

That is, according to the connection form of the resistance RS, the coaxial cable 11, and the terminal resistance 13 shown in FIG. 1, the resistance RS and the terminal resistance 13 form a voltage divider circuit that divides the transmission signal CVBS. Therefore, in the case of the terminal resistance 13 being normally connected to the coaxial cable 11, the voltage obtained by dividing the transmission signal CVBS by the voltage divider circuit is applied across both ends of the resistance RS. Here, the predetermined threshold voltage as a threshold for the voltage difference (|CPINH−CPINL|) is set based on the signal format of the analog information signal to be transmitted. That is, according to the signal format of the analog information signal to be transmitted, a minimum voltage value according to standards that may be continuously applied to the resistance RS for a predetermined period during transmission of the transmission signal CVBS can be confirmed. Therefore, the voltage value of the predetermined threshold voltage is set based on the minimum voltage value. Accordingly, in the case of the terminal resistance 13 being normally connected to the coaxial cable 11, the voltage generated across both ends of the resistance RS becomes equal to or greater than the predetermined threshold voltage described above. On the other hand, in the case of the terminal resistance 13 not being normally connected to the coaxial cable 11 and being in a connection failure state, the voltage divider circuit described above is not formed, so the voltage applied across both ends of the resistance RS becomes a minute voltage below the predetermined voltage described above.

Therefore, the terminal resistance abnormality detection circuit 22 incorporates the voltages applied across both ends of the resistance RS as the first detection voltage CPINH and the second detection voltage CPINL, respectively. Next, the terminal resistance abnormality detection circuit 22 generates a terminal resistance abnormality detection signal DS indicating whether the terminal resistance 13 is normally connected to the coaxial cable 11 or whether the terminal resistance 13 is in a connection failure state where the terminal resistance 13 is not normally connected to the coaxial cable 11 based on both detection voltages (CPINH, CPINL).

The terminal resistance abnormality detection circuit 22 supplies the generated terminal resistance abnormality detection signal DS to the control circuit 23.

The control circuit 23 supplies a control signal CNT that prompts stopping of transmission operation, for example, to the transmission circuit 21 in the case of the terminal resistance abnormality detection signal DS indicating “connection failure”. Therefore, the transmission circuit 21 that receives such control signal CNT stops its own transmission operation. At this time, the transmission circuit 21 may be set to a disable state according to such control signal CNT, or may cut off the power supplied to itself. Further, an output unit that outputs audio, display, or warning sound may be provided in the transmitting device 10, and the control circuit 23 may notify a user by audio, display, or warning sound that the terminal resistance 13 is not correctly connected to the coaxial cable 11 in the case of receiving the terminal resistance abnormality detection signal DS indicating “connection failure”.

Therefore, according to the transmitting device 10 including the terminal resistance abnormality detection circuit 22, the diode D1, and the resistance RS, it becomes probable to constantly detect connection failure of the terminal resistance 13 during transmission of not only an analog video signal but also various analog information signals other than the video signal.

### Second Embodiment

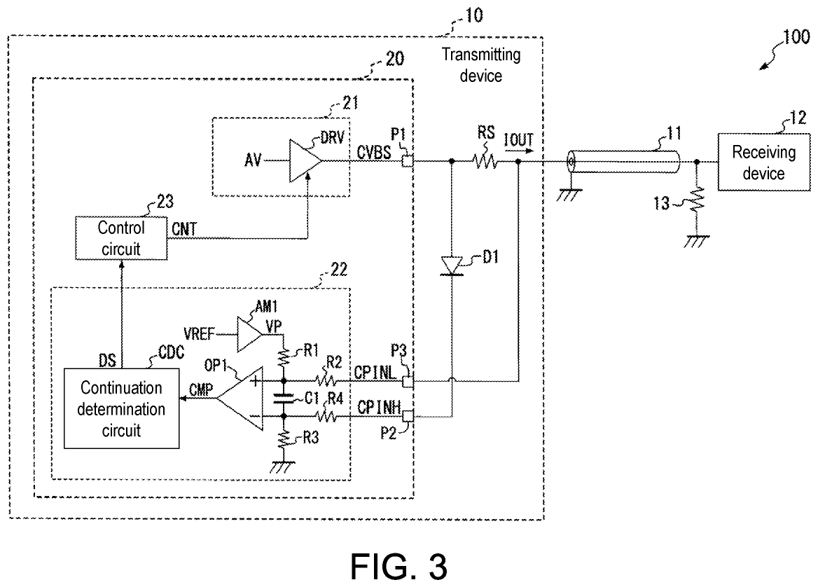

FIG. 3 is a diagram showing the configuration of the output unit in the transmission circuit 21 shown in FIG. 1, and the detailed circuit configuration of the terminal resistance abnormality detection circuit 22.

As shown in FIG. 3, the output unit of the transmission circuit 21 includes an output driver DRV that generates an amplified analog information signal AV to be transmitted as the transmission signal CVBS and outputs the same. The output driver DRV is set to a disable state that stops transmission operation according to a control signal CNT supplied from the control circuit 23.

The terminal resistance abnormality detection circuit 22 includes a comparison circuit including resistances R1 to R4, a capacitor C1, and a comparator OP1, an amplifier AM1, and a continuation determination circuit CDC.

The amplifier AM1 receives a predetermined reference voltage VREF, amplifies the same, and outputs the amplified voltage as a predetermined voltage VP, which is supplied to one end of the resistance R1. The other end of the resistance R1 is connected to the non-inverting input end of the comparator OP1 and one end of the resistance R2. The other end of the resistance R2 is connected to the terminal P3, and receives the second detection voltage CPINL via the terminal P3. One end of the resistance R3 is grounded, and the other end is connected to the inverting input end of the comparator OP1 and one end of the resistance R4. The other end of the resistance R4 is connected to the terminal P2, and receives the first detection voltage CPINH via the terminal P2. Each of the resistances R1 to R4 has the same resistance value and has a high voltage value that is significantly higher than the resistance values of the resistance RS and the terminal resistance 13. The capacitor C1 has one end connected to the inverting input end of the comparator OP1 and the other end connected to the non-inverting input end of the comparator OP1.

By the above-described comparison circuit (OP1, C1, R1 to R4), a voltage VinX input to the inverting terminal of the comparator OP1 is

VinX=CVBS/2
and
a voltage Vin input to the non-inverting terminal of the comparator OP1 is

VIN=[VP+(CVBS−IOUT·RE)]/2
IOUT: a current flowing through the resistance RS and the terminal resistance 13
re: a resistance value of the resistance RS and the terminal resistance 13 (75 ohms).

Here, in the case where VinX and Vin are the same,

CVBS=VP+CVBS−IOUT·re
and

VP=IOUT·re
can be derived.

That is, in the comparison circuit (OP1, C1, R1 to R4), in the case where the voltage difference (|CPINH−CPINL|) between the first detection voltage CPINH and the second detection voltage CPINL matches, the voltage VP applied to the resistance R1 is applied across both ends of the resistance RS.

Therefore, in the comparison circuit (OP1, C1, and R1 to R4) shown in FIG. 3, the voltage VP applied to the resistance R1 becomes a predetermined threshold voltage for the voltage difference (|CPINH−CPINL|) between the first detection voltage CPINH and the second detection voltage CPINL.

Thus, the comparator OP1 of the comparison circuit determines whether the voltage difference (|CPINH−CPINL|) between the first detection voltage CPINH and the second detection voltage CPINL is less than the voltage VP as the predetermined threshold voltage. At this time, in the case where it is determined that the voltage difference (|CPINH−CPINL|) is equal to or greater than the voltage VP, the comparator OP1 outputs a comparison result signal CMP of logic level 0 (or 1) indicating that the terminal resistance 13 is normally connected.

On the other hand, in the case where it is determined that the voltage difference (|CPINH−CPINL|) is less than the voltage VP, the comparator OP1 outputs a comparison result signal CMP of logic level 1 (or 0) indicating connection failure where the terminal resistance 13 is not normally connected to the coaxial cable 11. The comparator OP1 supplies the output comparison result signal CMP to the continuation determination circuit CDC.

Incidentally, in the comparison circuit (OP1, C1, and R1 to R4) shown in FIG. 3, a capacitance resistance (CR) filter including the capacitor C1, the resistance R2, and the resistance R4 is connected to the comparator OP1. The CR filter prevents transient operation during steep voltage changes of the detection voltages CPINH and CPINL and erroneous detection caused by the capacitance of the coaxial cable 11, or the like, for the comparator OP1 by the time constant of the capacitor C1, the resistance R2, and the resistance R4.

In the case of receiving a comparison result signal CMP of logic level 0 (or 1) indicating that the terminal resistance 13 is normally connected, the continuation determination circuit CDC generates a terminal resistance abnormality detection signal DS of logic level 0 (or 1) indicating “normal connection”. On the other hand, in the case of receiving a comparison result signal CMP of logic level 1 (or 0) indicating connection failure of the terminal resistance 13, the continuation determination circuit CDC determines whether the comparison result signal CMP has continued the state of logic level 1 (or 0) indicating connection failure of the terminal resistance 13 over a predetermined period. Here, in the case where it is determined that the state where the comparison result signal CMP indicates connection failure of the terminal resistance 13 has continued over the predetermined period, the continuation determination circuit CDC generates a terminal resistance abnormality detection signal DS of logic level 1 (or 0) indicating “connection failure”.

The continuation determination circuit CDC supplies the terminal resistance abnormality detection signal DS generated as described above to the control circuit 23. Incidentally, the operation of the control circuit 23 is the same as the operation shown in FIG. 1.

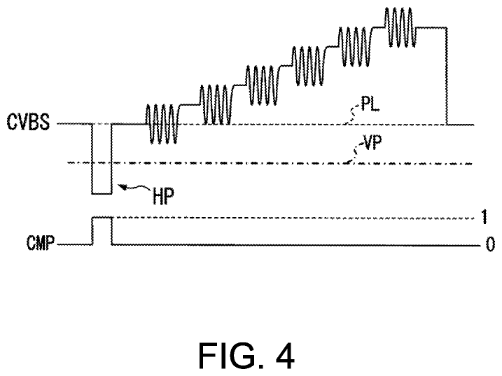

Next, a determination method for the voltage value of the voltage VP as the predetermined threshold voltage described above will be described with reference to FIG. 4, taking as an example the case where the information signal to be transmitted by the transmission circuit 21 is an analog video signal.

FIG. 4 is a waveform diagram showing a signal format of a transmission signal CVBS based on an analog video signal.

As shown in FIG. 4, the voltage of the transmission signal CVBS based on the analog video signal is applied from the transmission circuit 21 to one end of the terminal resistance 13 via the terminal P1, the resistance RS, and the coaxial cable 11.

Here, a horizontal sync pulse HP that appears once every horizontal sync period in the video signal is a pulse having a voltage lower than a pedestal level PL (for example, 0.286 volts) corresponding to brightness level 0. Therefore, as shown by the dash-dot line in FIG. 4, a voltage (for example, 0.2 volts) that is lower than the pedestal level PL and higher than the minimum voltage of the horizontal sync pulse HP is set as the voltage VP as the predetermined threshold voltage described above.

Accordingly, other than the horizontal sync pulse HP shown in FIG. 4, the transmission signal CVBS becomes equal to or higher than the voltage VP. Therefore, the comparison result signal CMP output from the comparison circuit (OP1, C1, R1 to R4) shows logic level 1 indicating connection failure of the terminal resistance 13 merely during the pulse width period of the horizontal sync pulse HP as shown in FIG. 4. On the other hand, during periods other than the pulse width period of the horizontal sync pulse HP, the comparison result signal CMP shows logic level 0 indicating that the terminal resistance 13 is normally connected. At this time, the predetermined period serving as a threshold for continuation determination in the continuation determination circuit CDC is set to a time longer than the pulse width period of the horizontal sync pulse HP. Accordingly, in the case where the terminal resistance 13 is normally connected to the coaxial cable 11, the continuation determination circuit CDC can generate the terminal resistance abnormality detection signal DS of logic level 0 indicating “normal connection”. That is, the continuation determination circuit CDC outputs the terminal resistance abnormality detection signal DS of logic level 1 indicating “connection failure” merely in the case where the state of logic level 1 in which the comparison result signal CMP indicates connection failure of the terminal resistance 13 continues for the predetermined period.

### Third Embodiment

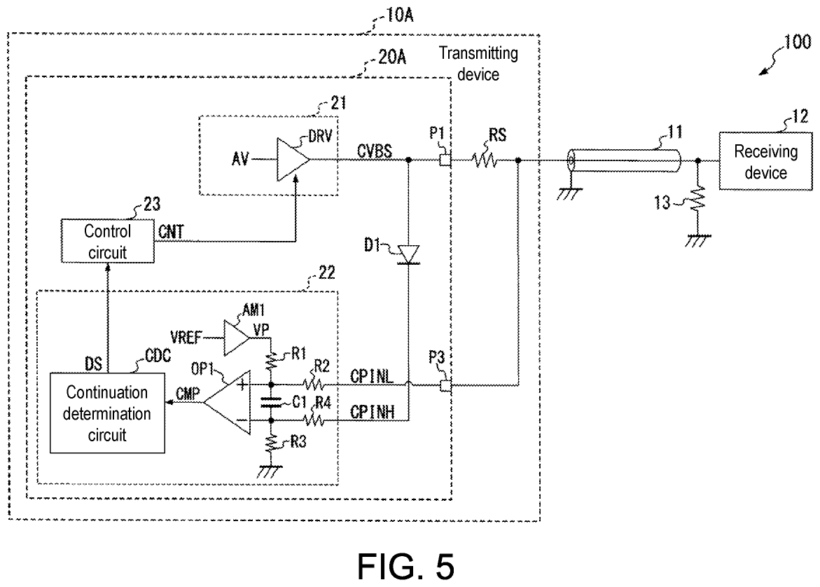

FIG. 5 is a block diagram showing a configuration of a communication system 100 including a transmitting device 10A as another embodiment of the transmitting device 10 shown in FIG. 3.

The transmitting device 10A adopts a transmission IC chip 20A in place of the transmission IC chip 20 shown in FIG. 3, and other configurations are the same as the configurations shown in FIG. 3, except that the diode D1 shown in FIG. 3 is provided inside the transmission IC chip 20A.

As shown in FIG. 5, by providing the diode D1 for noise countermeasure inside the transmission IC chip 20A, it becomes probable to reduce the number of external components and the number of terminals provided on the chip compared to the transmission IC chip 20.

The disclosure is not limited to the forms of the above-described embodiments, and various improvements and design changes can be made within a scope that does not depart from the spirit of the disclosure. For example, in the above-described embodiments, the transmitting device 10 (10A) and the receiving device 12 are connected by the coaxial cable 11, but a transmission line such as a twisted pair cable or RCA cable or the like may be used in place of the coaxial cable.

In short, the transmitting device of the disclosure that transmits a transmission signal (CVBS) to a receiving device via a transmission line (11) having a terminal resistance (13) and the receiving device (12) connected to one end thereof may include the following impedance matching resistance, transmission circuit, and terminal resistance abnormality detection circuit.

That is, the impedance matching resistance (RS) has one end thereof connected to the other end of the transmission line (11) and the other end connected to the transmitting device (10, 10A).

The transmission circuit (21) generates a transmission signal (CVBS) based on an information signal (AV), and outputs the generated transmission signal to the other end of the impedance matching resistance.

The terminal resistance abnormality detection circuit (22) outputs an abnormality detection signal (DS) indicating that the terminal resistance (13) is not normally connected to the transmission line (11) in the case where a voltage difference between a voltage (CPINH) at one end of the impedance matching resistance and a voltage (CPINL) at the other end of the impedance matching resistance becomes less than a predetermined threshold voltage (VP).

### Additional Notes

The present specification discloses the following configurations.

### (Configuration 1)

A transmitting device transmits a transmission signal to a receiving device via a transmission line having a terminal resistance and the receiving device connected to one end thereof, and the transmitting device includes: an impedance matching resistance having one end thereof connected to the other end of the transmission line and the other end thereof connected to the transmitting device; a transmission circuit that generates the transmission signal based on an information signal and outputs the generated transmission signal to the other end of the impedance matching resistance; and a terminal resistance abnormality detection circuit that outputs an abnormality detection signal indicating that the terminal resistance is not normally connected to the transmission line in the case where a voltage difference between a voltage at one end of the impedance matching resistance and a voltage at the other end of the impedance matching resistance becomes less than a predetermined threshold voltage.

### (Configuration 2)

In the transmitting device according to configuration 1, the terminal resistance abnormality detection circuit outputs an abnormality detection signal indicating that the terminal resistance is not normally connected to the transmission line in the case where a state in which the voltage difference becomes less than a predetermined threshold voltage continues for a predetermined period.

### (Configuration 3)

In the transmitting device according to configuration 2, the terminal resistance abnormality detection circuit includes: a comparator that receives the voltage at the other end of the impedance matching resistance as a first detection voltage at a non-inverting input end, receives the voltage at one end of the impedance matching resistance as a second detection voltage at an inverting input end, and receives the predetermined threshold voltage at the non-inverting input end via a resistance, thereby determining whether a voltage difference between the first detection voltage and the second detection voltage becomes less than the predetermined threshold voltage, and outputs a comparison result signal indicating connection failure of the terminal resistance in the case where the voltage difference is determined to be less than the predetermined threshold voltage; and a continuation determination circuit that outputs the abnormality detection signal in the case where the comparison result signal is continuously output from the comparator for the predetermined period.

### (Configuration 4)

The transmitting device according to configuration 3 includes a CR filter, and the CR filter includes: a capacitor having one end thereof connected to the non-inverting input end of the comparator and the other end thereof connected to the inverting input end of the comparator; a first resistance that receives the first detection voltage at one end thereof and has the other end thereof connected to the non-inverting input end of the comparator; and a second resistance that receives the second detection voltage at one end thereof and has the other end thereof connected to the inverting input end of the comparator.

### (Configuration 5)

The transmitting device according to any one of configurations 1 to 4 includes a diode having an anode thereof connected to the other end of the impedance matching resistance and supplying a voltage at a cathode thereof to the terminal resistance abnormality detection circuit as a voltage at the other end of the impedance matching resistance.

### (Configuration 6)

In the transmitting device according to configuration 5, the diode is a Schottky barrier diode, a fast recovery diode, or a high-speed diode.

### (Configuration 7)

In the transmitting device according to configuration 5 or 6, the transmission circuit and the terminal resistance abnormality detection circuit are formed on a semiconductor IC chip, and the impedance matching resistance and the diode are externally attached to the semiconductor IC chip.

### (Configuration 8)

In the transmitting device according to configuration 5 or 6, the transmission circuit, the terminal resistance abnormality detection circuit, and the diode are formed on a semiconductor IC chip, and the impedance matching resistance is externally attached to the semiconductor IC chip.

What is claimed is:

1. A transmitting device which transmits a transmission signal to a receiving device via a transmission line having a terminal resistance and the receiving device connected to one end thereof, the transmitting device comprising:
an impedance matching resistance, having one end thereof connected to the other end of the transmission line and the other end thereof connected to the transmitting device;
a transmission circuit, generating the transmission signal based on an information signal and outputting the transmission signal generated to the other end of the impedance matching resistance; and
a terminal resistance abnormality detection circuit, outputting an abnormality detection signal indicating that the terminal resistance is not normally connected to the transmission line when a voltage difference between a voltage at one end of the impedance matching resistance and a voltage at the other end of the impedance matching resistance becomes less than a predetermined threshold voltage.

2. The transmitting device according to claim 1, wherein the terminal resistance abnormality detection circuit outputs the abnormality detection signal indicating that the terminal resistance is not normally connected to the transmission line when a state where the voltage difference is less than the predetermined threshold voltage continues for a predetermined period.

3. The transmitting device according to claim 2, wherein the terminal resistance abnormality detection circuit comprises:
a comparator that receives the voltage at the other end of the impedance matching resistance as a first detection voltage at a non-inverting input end thereof, receives the voltage at one end of the impedance matching resistance as a second detection voltage at an inverting input end thereof, and receives the predetermined threshold voltage at the non-inverting input end via a resistance, thereby determining whether the voltage difference between the first detection voltage and the second detection voltage is less than the predetermined threshold voltage, and outputs a comparison result signal indicating connection failure of the terminal resistance when it is determined that the voltage difference is less than the predetermined threshold voltage; and
a continuation determination circuit that outputs the abnormality detection signal when the comparison result signal is continuously output from the comparator for the predetermined period.

4. The transmitting device according to claim 3, comprising a CR filter comprising:
a capacitor having one end thereof connected to the non-inverting input end of the comparator and the other end thereof connected to the inverting input end of the comparator;
a first resistance that receives the first detection voltage at one end thereof and has the other end thereof connected to the non-inverting input end of the comparator; and
a second resistance that receives the second detection voltage at one end thereof and has the other end thereof connected to the inverting input end of the comparator.

5. The transmitting device according to claim 1, comprising a diode having an anode thereof connected to the other end of the impedance matching resistance and supplying a voltage at a cathode thereof to the terminal resistance abnormality detection circuit as the voltage at the other end of the impedance matching resistance.

6. The transmitting device according to claim 5, wherein the diode is a Schottky barrier diode, a fast recovery diode, or a high-speed diode.

7. The transmitting device according to claim 5, wherein the transmission circuit and the terminal resistance abnormality detection circuit are formed on a semiconductor IC chip, and the impedance matching resistance and the diode are externally attached to the semiconductor IC chip.

8. The transmitting device according to claim 5, wherein the transmission circuit, the terminal resistance abnormality detection circuit, and the diode are formed on a semiconductor IC chip, and the impedance matching resistance is externally attached to the semiconductor IC chip.

9. The transmitting device according to claim 2, comprising a diode having an anode thereof connected to the other end of the impedance matching resistance and supplying a voltage at a cathode thereof to the terminal resistance abnormality detection circuit as the voltage at the other end of the impedance matching resistance.

10. The transmitting device according to claim 3, comprising a diode having an anode thereof connected to the other end of the impedance matching resistance and supplying a voltage at a cathode thereof to the terminal resistance abnormality detection circuit as the voltage at the other end of the impedance matching resistance.

11. The transmitting device according to claim 4, comprising a diode having an anode thereof connected to the other end of the impedance matching resistance and supplying a voltage at a cathode thereof to the terminal resistance abnormality detection circuit as the voltage at the other end of the impedance matching resistance.

12. The transmitting device according to claim 9, wherein the diode is a Schottky barrier diode, a fast recovery diode, or a high-speed diode.

13. The transmitting device according to claim 9, wherein the transmission circuit and the terminal resistance abnormality detection circuit are formed on a semiconductor IC chip, and the impedance matching resistance and the diode are externally attached to the semiconductor IC chip.

14. The transmitting device according to claim 9, wherein the transmission circuit, the terminal resistance abnormality detection circuit, and the diode are formed on a semiconductor IC chip, and the impedance matching resistance is externally attached to the semiconductor IC chip.

15. The transmitting device according to claim 10, wherein the diode is a Schottky barrier diode, a fast recovery diode, or a high-speed diode.

16. The transmitting device according to claim 10, wherein the transmission circuit and the terminal resistance abnormality detection circuit are formed on a semiconductor IC chip, and the impedance matching resistance and the diode are externally attached to the semiconductor IC chip.

17. The transmitting device according to claim 10, wherein the transmission circuit, the terminal resistance abnormality detection circuit, and the diode are formed on a semiconductor IC chip, and the impedance matching resistance is externally attached to the semiconductor IC chip.

18. The transmitting device according to claim 11, wherein the diode is a Schottky barrier diode, a fast recovery diode, or a high-speed diode.

19. The transmitting device according to claim 11, wherein the transmission circuit and the terminal resistance abnormality detection circuit are formed on a semiconductor IC chip, and the impedance matching resistance and the diode are externally attached to the semiconductor IC chip.

20. The transmitting device according to claim 11, wherein the transmission circuit, the terminal resistance abnormality detection circuit, and the diode are formed on a semiconductor IC chip, and the impedance matching resistance is externally attached to the semiconductor IC chip.
